(19) United States
(12) Patent Application Publication
(10) Pub. No.: US 2021/0005569 A1
(43) Pub. Date: Jan. 7, 2021

(54) GANG CLIP

(71) Applicant: TEXAS INSTRUMENTS INCORPORATED, Dallas, TX (US)

(72) Inventors: Michael Kirby Chua Quijano, Mabala (PH); Lorraine Duldulao Quijano, Mabalacat (PH)

(21) Appl. No.: 16/459,033

(22) Filed: Jul. 1, 2019

(51) Int. Cl. H01L 23/00; H01L 23/495; H01L 25/00; H01L 21/48; H01L 25/065

(52) U.S. Cl. CPC H01L 24/40; H01L 2224/84815; H01L 23/49513; H01L 23/49575; H01L 24/41; H01L 24/83; H01L 24/84; H01L 25/50; H01L 21/4842; H01L 24/32; H01L 24/73; H01L 25/0657; H01L 24/92; H01L 2224/32245; H01L 2224/40245; H01L 2224/4118; H01L 2224/73263; H01L 2225/06572; H01L 2224/40145; H01L 2224/92246; H01L 2224/37147; H01L 2224/83815; H01L 23/49541

(57) ABSTRACT

An integrated circuit (IC) package includes a lead frame and a first die attached to the lead frame. The IC package also includes a first clip attached to first die and the lead frame. The IC package further includes a second die attached to first clip and the lead frame. The IC package still further includes a second clip with a clip foot adhered to the lead frame on a first side of the second clip, the second clip extending to and contacting a side of the second die via a layer of solder paste. The second clip includes a sawn or lased edge at a second side of the second clip opposing the first side of the second clip.

### TECHNICAL FIELD

This disclosure relates to integrated circuit (IC) packages, and more particularly, to an IC packages that implement a gang clip.

### BACKGROUND

Increasing power levels and power density requirements for multiple end products means that high-power semiconductor modules and components are often assembled using a clip-bonding technology. Solder paste leaves flux residues on solder joints and must be cleaned from high-power modules to meet high reliability requirements.

In contrast to the techniques of attaching a die by adhesive bonding or wire soldering, high-power packages and discrete devices, such as metal oxide semiconductor field effect transistors (MOSFETs), insulated gate bipolar transistors (IGBTs), and switched output differential structures (SODs) use solder paste to connect the die to the basic substrate and/or leads. Clip-bonding technology partially replaces the standard wire-bond connection between a die and a lead by a clip (e.g., a copper clip), which is also soldered by solder paste. Clip bonding allows for unique package resistance, better thermal transfer, and ultra-fast switching performance due to the small package.

### SUMMARY

One example relates to an integrated circuit (IC) package having a lead frame and a first die adhered to the lead frame on a first side of the first die. The IC package also includes a first clip having a clip foot adhered to the lead frame, the first clip extending from the lead frame and contacting a second side of the first die on a first side of the first clip via a first layer of solder paste wherein the second side of the first die opposes the first side of the first die. The IC package further includes a second die with a first side adhered to a second side of the first clip via a second layer of solder paste, wherein the second side of the first clip opposes the first side of the first clip. The IC package still further includes a second clip having a clip foot adhered to the lead frame on a first side of the second clip, the second clip extending from the lead frame to a second side of the second die via a third layer of solder paste. The second side of the second die opposes the first side of the second die, wherein the second clip has an sawn or lased edge on a second side of the second clip, wherein the second side of the second clip opposes the first side of the second clip.

Another example relates to a method for forming an IC package. The method includes forming a first layer of solder paste on a lead frame. The method also includes adhering a first die to the lead frame on a first side of the first die via the first layer of solder paste. The method further includes forming a second layer of solder paste on a second side of the first die, the second side of the first die opposing the first side of the first die. The method yet further includes adhering a clip foot of a clip to the lead frame and adhering a first side of the first clip to the second side of the first die via the second layer of solder paste. The method still further includes forming a third layer of solder paste on a second side of the first clip. The second side of the first clip opposes the first side of the first clip and adhering a second die on the second side of the first clip via the third layer of solder paste. The method also includes forming a fourth layer of solder paste on a first side of a second clip and adhering a first clip foot on a first side of the second clip to the lead frame and adhering the second clip to the second side of the second die via the fourth layer of solder paste, and wherein a second clip foot on a second side of the second clip rests on the lead frame on that opposes the first side of the second clip. The method further includes reflowing the first layer, the second layer, the third layer and the fourth layer of solder paste.

Yet another relates to an IC package including a lead frame a first die attached to the lead frame and a first clip attached to first die and the lead frame. The IC package also includes a second die attached to first clip and the lead frame and a second clip with a clip foot adhered to the lead frame on a first side of the second clip. The second clip extending to and contacting a side of the second die via a layer of solder paste. The second clip includes a sawn or lased edge at a second side of the second clip that opposes the first side of the second clip.

### BRIEF DESCRIPTION OF THE DRAWINGS

FIG. 1 illustrates a diagram of an example of an integrated circuit (IC) package.

FIG. 2 illustrates an example of an IC package with a clip that has a single clip foot.

FIG. 3 illustrates an example of a clip with a single clip foot for each IC structure.

FIG. 4 illustrates an example of a clip with two clip feet for each IC structure.

FIG. 5 illustrates a free body diagram of an example clip.

FIG. 6 illustrates an example of a panel of IC structures.

FIG. 7 illustrates an example of an IC structure with a clip with two feet prior to singulation.

FIG. 8 illustrates a flowchart of an example method forming an IC package.

### DETAILED DESCRIPTION

This disclosure relates to an IC package with a clip, such as a gang clip. The gang clip refers to a clip that overlays a plurality of frames in a lead frame. The clipped die structure includes a first clip (e.g., a copper clip) sandwiched between a first die and a second die. A second clip (e.g., a gang clip) includes a first clip foot adhered to a lead frame. The second clip also includes a high side that overhangs the clipped die structure and contacts a side of the second die via a layer of solder paste. The second clip initially includes a second foot (e.g., a dummy foot) that rests against the lead frame to prevent tilting of the second clip and the clip of the clipped die structure during solder reflow. Furthermore, during singulation, the second clip foot is removed in a sawing or lasing process. The prevention of tilting ensures that the layer of solder paste between the second clip and the second die has a nearly constant thickness bond line thickness (BLT) (e.g., within 10 micrometers (μm). Additionally, the prevention of tilting prevents an unwanted short between the second clip and the second die.

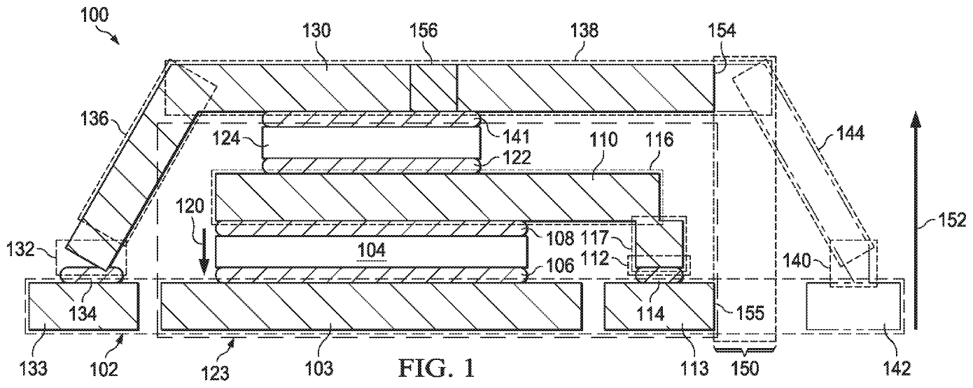

FIG. 1 illustrates a diagram of an example of an IC package 100 in a condition for completing packaging. The IC package 100 employs clip bonding techniques to bond the dies of the IC package to a lead frame 102. As used herein, the term “lead frame” refers to a structure an IC package that carries signals between dies of the IC package and external components, wherein the structure has been singulated from a lead frame strip. As one example, the lead frame 102 is a lead frame for a quad-flat no leads (QFN) IC package. In other examples, the lead frame 102 is employable in other types of IC packages. The IC package 100 is implemented as a multi-die IC package. In the examples illustrated, there are two dies, but in other examples, there could be more than two dies.

A bottom of a first die 104 overlaying the lead frame 102 is adhered and coupled to a first portion 103 of the lead frame 102 via a first layer of solder paste 106. A second layer of solder paste 108 overlays the first die 104. For purposes of simplification of explanation the terms top and bottom are employed throughout this disclosure to denote opposing surfaces. Similarly, the terms overlay, underlie, vertical and horizontal (and their derivatives) are employed to denote relative positions in a described arrangement. Moreover, the examples used throughout this disclosure denote one possible orientation. However, other orientations are possible (e.g., upside down, rotated by 90 degrees, etc.).

A first clip 110 includes a clip foot 112 adhered to a second portion 113 of the lead frame 102 via solder paste 114. As used herein, the term “clip” refers to a rigid copper bridge employed to implement clip bonding between a lead frame (e.g., the second portion 113 of the lead frame 102) and one or more dies (e.g., the first die 104) of an IC package (e.g., the IC package 100). Additionally, as used herein, the term “clip foot” refers to a region a clip that is adhered to a lead frame. In some examples, the solder paste 114 is formed with the first layer of solder paste 108 in a prior etching process. The first clip 110 extends from the clip foot 112 to a high side 116 via a tilted pillar 117 of the first clip 110. The high side 116 is implemented as a cantilever (e.g., a beam) that overlays the first die 104. The high side 116 of the first clip 110 is adhered and electrically coupled to the first die 104 via the second layer of solder paste 108. The high side 116 applies a force in a direction indicated by an arrow 120 (e.g., a downward force).

A third layer of solder paste 122 overlays the first clip 110. Additionally, a second die 124 overlays the first clip 110. More particularly, the second die 124 is adhered and, in some examples, electrically coupled to the first clip 110 via the third layer of solder paste 122. Moreover, in some examples, the second die 124 has a smaller footprint than the first die 104. In the example illustrated, the IC package 100 includes a clipped die structure 123 that is representative of the first clip 110 sandwiched between the first die 104 and the second die 124 via the second layer of solder paste 108 and the third layer of solder paste 122. The clipped die structure 123 also refers to the first portion 103 of the lead frame 102 and the second portion 113 of the lead frame 102, as well as portion of the first layer of solder paste 106 that couples the first die 104 to the lead frame 102 and the portion of solder paste 114 that couples the first clip 110 to the second portion 113 of the lead frame.

A second clip 130, such as a gang clip, includes a first clip foot 132 adhered to a third portion 133 of the lead frame 102 on via a solder paste 134. In some examples, the second clip 130 is a solid copper bridge (e.g., a copper clip). Additionally, in some examples, the second clip 130 represents a singulated portion of a larger second clip that (prior to singulation) contacted multiple dies in an array of IC structures. A corner of the first clip foot 132 is adhered to the third portion 133 of the lead frame 102. The solder paste 134 is a partition of the first layer of solder paste 106 that has been etched away. The second clip 130 includes a tilted pillar 136 extending from the first clip foot 132 of the second clip 130 to a high side 138 of the second clip 130. The high side 138 of the second clip 130 is a planer region on the second clip 130. In some examples, the tilted pillar 136 of the second clip 130 extends from the first clip foot 132 at an oblique angle. Stated differently, the tilted pillar 136 of the second clip 130 extends from the lead frame 102 at an angle other than 90 degrees.

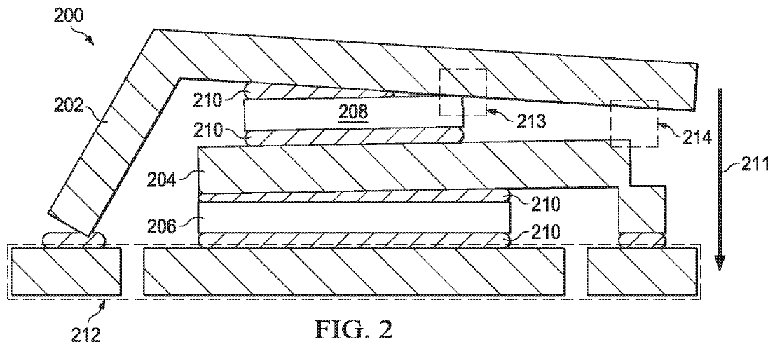

FIG. 2 illustrates an example of an IC package 200 that demonstrates problems associated with a singled footed second clip 202 that overhangs a first clip 204 that is sandwiched between a first die 206 and a second die 208 with solder paste 210. During packaging of the IC package 200, both the second clip 202 and the first clip 204 apply a force a direction indicated by an arrow 211. More particularly, during reflow of the solder paste 210, the first clip 204 and the second clip 202 pivot about a lead frame 212 and apply uneven downward pressure indicated by the force 211 that causes the solder paste 210 to extrude unevenly in horizontal directions, such that the some or all of the instances of solder paste have an uneven bond line thickness (BLT). As used herein, “BLT” refers to a thickness of solder paste between two components of an IC package.

In the example illustrated, the uneven BLT of the solder paste, after reflow results in the second clip 202 directly contacting the second die 208. More specifically, the second clip 202 directly contacts the second die 208 without intermediate solder paste, resulting in a short circuit indicated at 213 between the second clip 202 and the second die 208. In some examples if the pivot of the second clip 202 is too extreme during reflow of the solder paste 210, the second clip 202 may contact the first clip 204 in another short indicated near an area indicated at 214.

Referring back to FIG. 1, to address problems associated with the IC package 200 of FIG. 2, the second clip 130 includes a second clip foot 140 that rests on a fourth portion 142 of the lead frame 102. In some examples, the second clip foot 140 of the second clip 130 is adhered to the fourth portion 142 of the lead frame 102. In other examples, the second clip 130 is un-bonded to the fourth portion 142 of the lead frame 102. A second tilted pillar 144 extends at an oblique angle from the fourth portion 142 of the lead frame 102 to the high side 138 of the second clip 130. The fourth portion 142 of the lead frame 102, the second tilted pillar 144 and a portion of the high side 138 are each illustrated with dotted lines. The dotted lines identify a portion of the second clip 130 and the lead frame 102 that are removed during a packaging operation of the IC package 100. More particularly, in some examples, the IC package 100 is coupled to other IC packages and during singulation, a region of the IC package 100 referred to as a saw street 150 is sawn or lased through or otherwise cut away from the remaining portion of the IC package 100 to separate the IC package 100 from the other IC packages. In other examples, the IC package 100 is packaged as an individual IC package. In such a situation, the saw street is sawn in a packaging operation.

The high side 138 of the second clip 130 is implemented as a cantilever (e.g., a beam) that is adhered, and in some examples electrically coupled to the second die 124 via a fourth layer of solder paste 141. In some examples, the fourth layer of solder paste 141 is implemented as a solder pillar. During reflow of solder, the high side 138 is shaped to apply a force indicated by an arrow 152 (e.g., an upward force). In some examples, the reflow process of the solder paste includes a reflowing of the first layer of solder paste 106, the second layer of solder paste 108, the third layer of solder paste 122 and the fourth layer of solder paste 141. During the reflow process, the second clip foot 140 of the second clip 130 prevents tilting (or pivoting) of the second clip 130. The prevention of the tilting (e.g., anti-tilting) results in a nearly constant (e.g., within 10 μm) BLT throughout the area of the fourth layer of solder paste 141. Further, in some examples, during the reflow process, the force 152 opposes the force 120, such that the first clip 110 is also prevented from tilting or pivoting. In this situation, the first layer of solder paste 106, the second layer of solder paste 108 and the third layer of solder paste 122 (or some subset thereof) also have a nearly constant BLT (e.g., within 10 μm).

After reflow, the IC package 100 is cut (e.g., sawn or lased) through the saw street 150, thereby removing the fourth portion 142 of the lead frame 102, the second tilted pillar 144 and a portion of the high side 138 of the second clip 130. However, after reflow, the solder paste, including the first layer of solder paste 106, the second layer of solder paste 108, the third layer of solder paste 122 and the fourth layer of solder paste 141 are rigid (e.g., hardened), and further extrusion of the solder paste is avoided. Additionally, the second clip 130 avoids direct contact with the second die 124. Stated differently, the second clip 130 contacts, and in some examples, is electrically coupled to the second die 124 only through the fourth layer of solder paste 141. Furthermore, the resultant second clip 130 includes an edge 154 that has been sawn or lased (alternatively referred to as a sawn or lased edge) that has residue remnant from the sawn off portion of the high side 138 of the second clip 130. The edge 154 of the second clip 130 is on a side of the second clip 130 that opposes the side of the second clip 130 with the first clip foot 132. In the resultant IC package 100, the high side 138 of the second clip 130 overhangs the first clip 110. More particularly, the high side 138 extends over the first clip 110, including the tilted pillar 117 of the first clip 110. Moreover, the edge 154 abuts the saw street 150, such that the edge 154 of the second clip 130 is parallel to an edge 155 of the lead frame 102 because the second clip foot 140 prevented tilting of the second clip 130 during removal (sawing of lasing) of the second tilted pillar 144 and the portion of the high side 138 of the second clip 130. Additionally, in some examples, the high side 138 of the second clip 130 has residue 156 remnant from a tie bar or multiple tie bars on a surface of the high side of that is orthogonal to the edge 154.

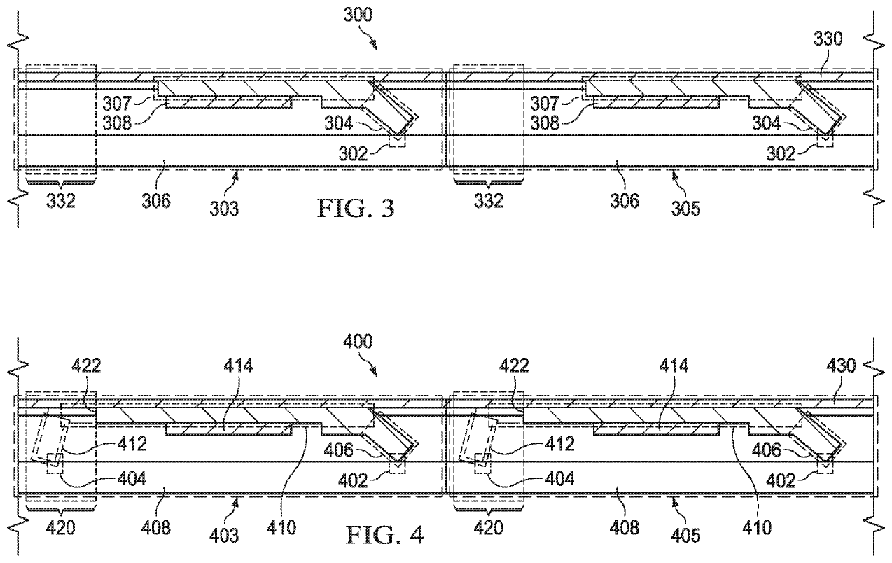

FIG. 3 illustrates an example of a clip 300 (such as a gang clip) with a single clip foot 302 and problems associated with the design. The clip 300 includes a first portion 303 for adherence to a first IC structure and a second portion 305 for adherence to a second IC structure. The first portion 303 and the second portion 305 have the same reference numbers to denote different instances of the same structure. The first portion 303 and the second portion 305 of the clip 300 includes a tilted pillar 304 that extends from a substrate 306 at an oblique angle to a high side 307. A solder pillar 308 implemented as a layer of solder paste is adhered to a bottom side (e.g., a first side) of the high side 307.

The first portion 303 and the second portion 305 of clip 300 are configured to be adhered to a die. More particularly, the first portion 303 and the second portion 305 of the clip 300 are configured to be positioned to overlay a die of a respective IC structure and each high side 307 is adhered to the respective die via the solder pillar 308. In such a situation, upon reflow of the solder pillar 308, the clip tilts (e.g., pivots about corner the clip foot 302), such that the solder pillar 308 between the respective die and the high side 307 has an uneven BLT and/or a short between the clip 300 and the die.

As noted, the clip 300 includes the first portion 303 for a first IC package structure and the second portion 305 for a second IC package structure. In such a situation, the clip 300 can be a constituent component for more IC packages, as discussed herein. In such a situation, a beam 330 extends horizontally across the clip 300. Moreover, during singulation, a saw street 332 of the first portion 303 and the second portion 305 of the clip 300 are sawn through during singulation.

FIG. 4 illustrates an example of a clip 400 that addresses the problems associated with the clip 300 of FIG. 3. In some examples, the clip 400 is employed to implement the second clip 130 of FIG. 1. The clip 400 includes a first clip foot 402 and a second clip foot 404, which second clip foot 404 is alternatively referred to as a dummy foot. The clip 400 includes a first portion 403 and a second portion 405 for adherence to a first IC package structure and a second portion 305 for adherence to a second IC package. The first portion 403 and the second portion 405 have the same reference numbers to denote different instances of the same structure. The first portion 403 and the second portion 405 of the clip 400 includes a first tilted pillar 406 that extends from a substrate 408 at an oblique angle to a high side 410. The high side 410 extends to a second tilted pillar 412 attached to the second clip foot 404. Each of the first portion 403 and the second portion 405 of the clip 400 includes a solder pillar 414 implemented as a layer of solder paste is adhered to a bottom side (e.g., a first side) of the high side 410.

The second tilted pillar 412 of the first portion 403 and the second portion 405 also extends from the substrate 408 at an oblique angle. In some examples, the second tilted pillar 412 extends from the substrate 408 at a different angle than the first tilted pillar 406. In other examples, the second tilted pillar 412 extends from the substrate 408 at the same angle as the first tilted pillar 406.

The first portion 403 and the second portion 405 of the clip 400 are configured to be adhered to a respective die, such as the second die 124 of FIG. 1, via the solder pillar 414 and a lead frame, such as the lead frame 102 of FIG. 1. Moreover, during reflow of the solder pillar 414, inclusion of the second clip foot 404 prevents tilting of the clip 400. Thus, after reflowing, the resultant layer of solder paste (formed from reflowing of the solder pillar 414) has a nearly constant (e.g., within 10 μm) BLT. That is, the inclusion of the second clip foot 404 prevents an undesired tilting (e.g., anti-tilting) of the clip 400.

The second clip foot 404, the second tilted pillar 412 and a portion of the high side 410 are removable from the first portion 403 and the second portion 405 of the clip 400 after the reflow of the solder. In particular, after reflow and during singulation, a saw street 420 of the first portion 403 and the second portion 405 is sawn with a saw or a laser to remove material and to define an edge 422 in the high side 410. In some examples, the edge 422 includes an interface with remnant residue from the sawn off portion of the high side 410.

As noted, the clip 400 includes the first portion 403 for a first IC package and the second portion 405 for a second IC package. In such a situation, the clip 400 can be a constituent component for more IC packages, as discussed herein. In such a situation, a beam 430 extends horizontally across the clip 400. Furthermore, in some examples, the clip 400 can be merged with the clip 300 of FIG. 3 for a panel of IC structures, as discussed herein.

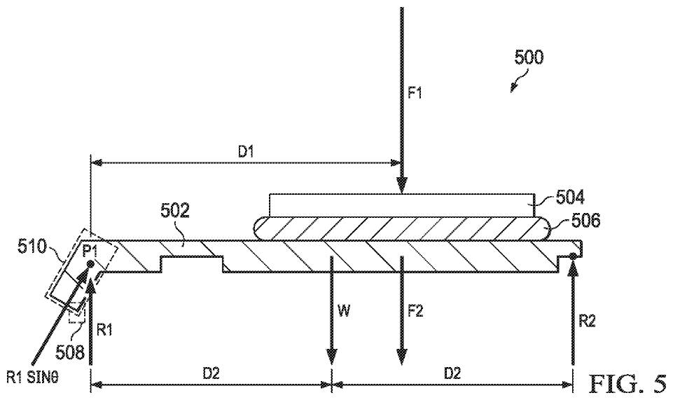

FIG. 5 illustrates a free body diagram 500 that includes an example of a clip 502 that is employable to implement the first clip 110 of FIG. 1. In particular, the clip 502 is adhered to a die 504 via a layer of solder paste 506. The clip 502 includes a clip foot 508 and a tilted pillar 510. The tilted pillar 510 is set at an angle, θ, which is an oblique angle.

The free body diagram 500 includes lines representing different forces applied on the clip 502. The free body diagram 500 includes a first force, F1 that presents a downward force applied by the die 504. The first force, F1 is separated by a pivot point, P1 by a first distance, D1. The free body diagram 500 also includes a weight, W representing a force due to gravity. The free body diagram 500 includes a second force, F2 representing a net downward force. The free body diagram 500 includes a reactive force, R1 SIN θ, which is representative of an angled upward force applied by the clip foot 508 and the tilted pillar 510. The free body diagram 500 includes a first reactive force, R1 representative of a net upward force at a distance D2 from the weight, W.

Inclusion of the second clip such as the second clip 130 of FIG. 1 during reflow results in a second reactive force, R2 representative of a net upward force at the second distance, D2 from the weight, W. In some examples, the second reactive force, R2 is representative of an upward force applied by a second clip with two feet, such as the second clip 130 of FIG. 1. The first reactive force R1 and the second reactive force R2 offset the second force, F2 (the net downward force). Thus, the second reactive force R2 provide a support structure that achieves equilibrium preventing bending of the clip 502 about the pivot point, P1. Prevention of bending allows the solder paste 506 to have a nearly constant (e.g., within 10 μm) BLT.

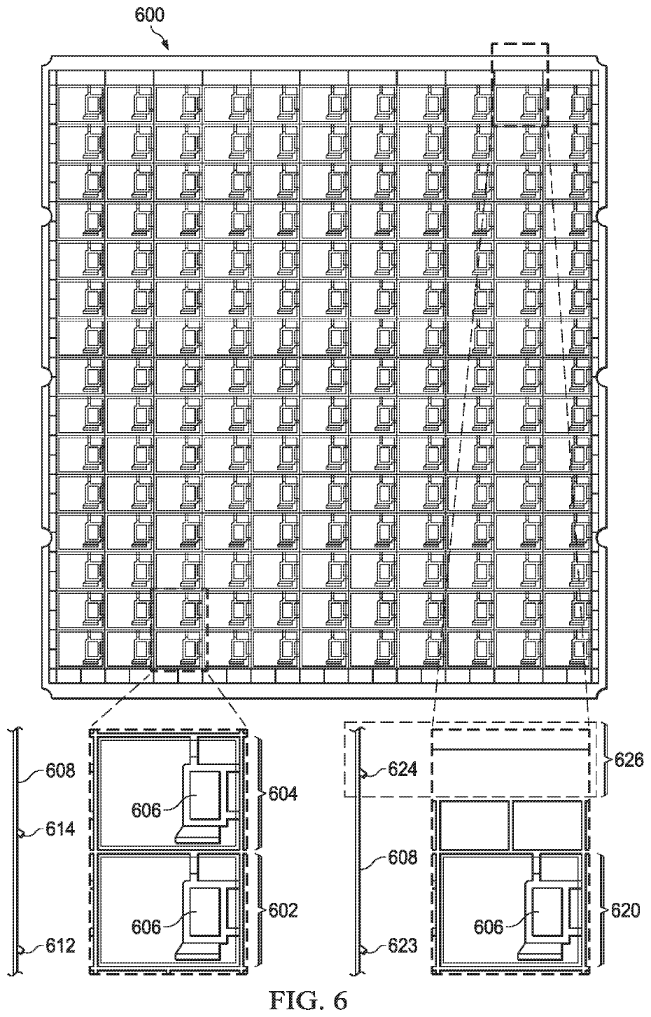

FIG. 6 illustrates a panel 600 (e.g., an array) of IC structures for packaging. The panel 600 includes fifteen rows and eleven columns. However, in other examples, there could be more or less columns and rows of IC structures. In the example illustrated, some of the IC chip structures, including a first IC structure 602 in a first of the panel 600 and a second IC structure 604 in a second row of the panel 600 of the same column, namely the sixth column. The first IC structure 602 and the second IC structure 604 in the sixth column are illustrated in an expanded view.

The first IC structure 602 and the second IC structure 604 each include a die 606. During a packaging process, a second clip 608, such as the second clip 300 of FIG. 3 (with a single clip foot for each respective IC structure) is positioned on the die 606 of the first IC structure 602 and the die 606 of the second IC structure. The second clip 608 includes at least sixteen clip feet, corresponding to the number of rows in the panel 600, and at least one extra clip foot, as explained herein. The clip feet are spaced to rest on a lead frame of the corresponding IC structure. In the case of the first IC structure 602, a first clip foot 612 of the second clip 608 rests against the first IC structure 602 and the second clip foot 614 rests against the second IC structure 604. In this manner, the second clip foot 614 provides support that prevent tilting on the portion of the second clip 608 that overlays the first IC structure 602. Similarly, a clip foot associated with an IC structure in a same column (e.g., the sixth column) and a subsequent row (e.g., the third row) as the second IC structure 604 provides structural support for the second IC structure 604.

The IC structure 620 in the final row (e.g., the 15 row) of the sixth column is also illustrated in an expanded view. However, the final row (e.g., the fifteenth row), there is no subsequent IC structure on which any portion of the second clip 608 rests. Thus, the second clip 608 includes a fifteenth clip foot 623 and a dummy clip foot 624 (e.g., the at least one extra clip foot) that is positioned in a saw street 626 of the IC structure 620. In this manner, during packaging, the second clip 608 of associated with the IC structure 620 has two clip feet, namely, a first clip foot 623 (the fifteenth clip foot overall) and a second clip foot 624 (the dummy clip foot). The second clip 608 can be implemented, for example, as the first portion 403 or the second portion 405 of the clip 400 illustrated in FIG. 4. After reflow of solder, the dummy clip foot 624 is removed during a singulation process (e.g., by sawing through the saw street 626). Inclusion of the dummy clip foot 624 curtails tilting of solder paste to provide a reflowed solder paste between the second clip 608 and the respective die 606 that has a nearly constant (e.g., within 10 μm) BLT.

In some examples, the second clip 608 employed for each row (or some subset thereof) of in the panel 600 includes a dummy foot (similar to the dummy clip foot 624) that is removed during singulation. In other examples, the second clip 608 includes a dummy foot (e.g., the dummy clip foot 624) in a last row.

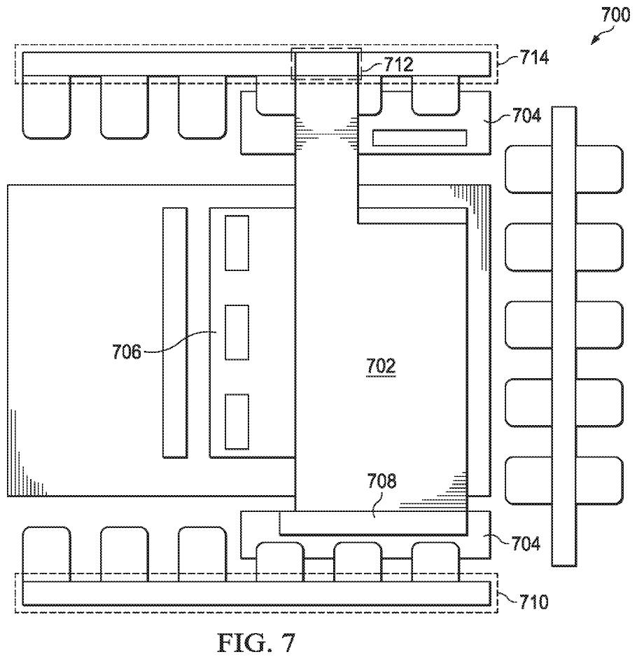

FIG. 7 illustrates an example of an IC structure 700 with a second clip 702 adhered to a lead frame 704 and a die 706 via a layer of solder paste. The IC structure 700 is representative of an example of the IC structure 620 of FIG. 6 prior to singulation. The second clip 702 includes a first clip foot 708 that is proximal to a first saw street 710. The second clip 702 also includes a second clip foot 712 (e.g., a dummy clip foot) that is within a second saw street 714.

Inclusion of the second clip foot 712 prevents tilting of the second clip 702 during solder reflow, as discussed herein. Further, the second clip 702 provides an upward force on a clip (hidden from view in FIG. 7) of the IC structure 700 to curtail tilting of the second clip. During singulation, the first saw street 710 and the second saw street 714 are sawn off (e.g., in a sawing or lasing process). Sawing of the second saw street 714 removes the second clip foot 712 from the remaining portion of the second clip 702.

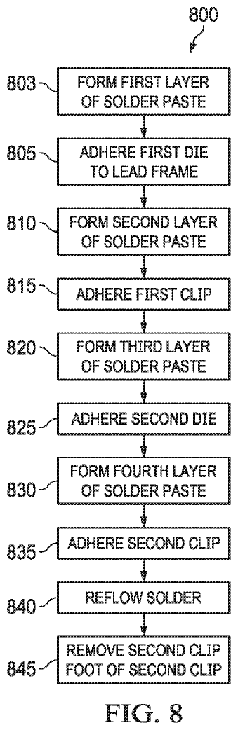

FIG. 8 illustrates a method 800 for forming an IC package. The method could be employed for example, to form the IC package 100 of FIG. 1. At 803, a first layer of solder paste is formed on a lead frame. At 805, a first die (e.g., the first die 104 of FIG. 1) is adhered to a lead frame (e.g., the lead frame 102 of FIG. 1) on a first side of the first die via the first layer of solder paste. At 810, a second layer of solder paste is formed on a second side of the first die, the second side of the first die opposing the first side of the first die. At 815, a first clip is adhered to the lead frame and a first side of the clip is adhered to the second side of the first die via the second layer of solder paste. At 820, a third layer of solder paste is formed on a second side of the first clip, wherein the second side of the clip opposes the first side of the clip.

At 825, a second die (e.g., the second die 124 of FIG. 1) is adhered to the second side of the first clip via the third layer of solder paste. At 830, a fourth layer of solder paste (e.g., a solder pillar) is formed on a first side of a second clip (e.g., the second clip 130 of FIG. 1). At 835, a first clip foot of the second clip is adhered to the lead frame and a high side of the second clip is adhered to the second die via the fourth layer of solder paste, and wherein a second clip foot of the second clip rests on the lead frame. At 840, the first layer, the second layer, the third layer and the fourth layer of solder paste are reflowed, and the inclusion of the first and second clip foots of the second clip ensure the fourth layer of solder paste has a nearly constant bond line thickness (BLT) (e.g., within 10 μm). In some examples, additional dies may added for the IC package through further processing operations. At 845 the second clip foot of the second clip is removed during a sawing of a saw street (e.g., the saw street 150 of FIG. 1).

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

What is claimed is:

1. An integrated circuit (IC) package comprising:
a lead frame;
a first die adhered to the lead frame on a first side of the first die;
a first clip having a clip foot adhered to the lead frame, the first clip extending from the lead frame and contacting a second side of the first die on a first side of the first clip via a first layer of solder paste wherein the second side of the first die opposes the first side of the first die;
a second die with a first side adhered to a second side of the first clip via a second layer of solder paste, wherein the second side of the first clip opposes the first side of the first clip; and
a second clip having a clip foot adhered to the lead frame on a first side of the second clip, the second clip extending from the lead frame to a second side of the second die via a third layer of solder paste, the second side of the second die opposing the first side of the second die, wherein the second clip has an sawn or lased edge on a second side of the second clip, wherein the second side of the second clip opposes the first side of the second clip.

2. The IC package of claim 1, wherein the sawn or lased edge is parallel to an edge of the lead frame.

3. The IC package of claim 1, wherein the second clip comprises a high side that includes the sawn or lased edge, and wherein a surface of the high side that is orthogonal to the lased or sawn edge includes residue remnant from a tie bar.

4. The IC package of claim 1, wherein the second clip applies a force which offsets at least a portion of a force applied by the first clip on the first layer of solder paste.

5. The IC package of claim 4, wherein the sawn or lased edge of the clip foot extends to a saw street of the lead frame.

6. The IC package of claim 5, wherein a portion of the second clip extends over the clip foot of the first clip.

7. The IC package of claim 1, wherein IC package is a quad-flat no leads (QFN) package.

8. The IC package of claim 1, wherein the second clip extends from the clip foot of the second clip away from the lead frame at an oblique angle.

9. The IC package of claim 1, wherein the second clip is positioned to avoid direct contact with the second die.

10. A method for forming an integrated circuit (IC) package, the method comprising:
forming a first layer of solder paste on a lead frame;
adhering a first die to the lead frame on a first side of the first die via the first layer of solder paste;
forming a second layer of solder paste on a second side of the first die, the second side of the first die opposing the first side of the first die;
adhering a clip foot of a first clip to the lead frame and adhering a first side of the first clip to the second side of the first die via the second layer of solder paste;
forming a third layer of solder paste on a second side of the first clip, wherein the second side of the first clip opposes the first side of the first clip;
adhering a second die on the second side of the first clip via the third layer of solder paste;
forming a fourth layer of solder paste on a first side of a second clip;
adhering a first clip foot on a first side of the second clip to the lead frame and adhering the second clip to the second side of the second die via the fourth layer of solder paste, and wherein a second clip foot on a second side of the second clip rests on the lead frame on that opposes the first side of the second clip; and
reflowing the first layer, the second layer, the third layer and the fourth layer of solder paste.

11. The method of claim 10, further comprising:
removing the second clip foot of the second clip after the reflowing.

12. The method of claim 11, wherein the removing is executed in a sawing or lasing process.

13. The method of claim 10, wherein the second clip applies a first force that opposes a second force applied by the first clip to the first die during the reflowing.

14. The method of claim 10, wherein a portion of the second clip extends over a saw street of the lead frame.

15. An integrated circuit (IC) package comprising:
a lead frame;
a first die attached to the lead frame;
a first clip attached to first die and the lead frame;
a second die attached to first clip and the lead frame; and
a second clip with a clip foot adhered to the lead frame on a first side of the second clip, the second clip extending to and contacting a side of the second die via a layer of solder paste, wherein the second clip includes a sawn or lased edge at a second side of the second clip opposing the first side of the second clip.

16. The IC package of claim 15, wherein the sawn or lased edge is parallel to an edge of the lead frame.

17. The IC package of claim 15, wherein the second clip applies a force to offset at least a portion of a force applied by the first clip on a layer of solder paste between the first clip and the first die.

18. The IC package of claim 15, wherein the sawn or lased edge of the second clip extends to a saw street of the lead frame and over the clip foot of the first clip.

19. The IC package of claim 15, wherein the second clip is positioned to avoid direct contact with the second die.

20. The IC package of claim 15, wherein the second clip extends away from the lead frame at an oblique angle.
